(19) United States
(12) Patent Application Publication
(10) Pub. No.: US 2015/0043068 A1
(43) Pub. Date: Feb. 12, 2015

(54) MEDICAL IMAGING DEVICE WITH LENTICULAR IMAGE

(71) Applicant: SIEMENS AKTIENGESELLSCHAFT, MUNCHEN (DE)

(72) Inventors: HANNO DOTZEL, LANGENSENDELBACH (DE); RAINER KIRSCH, BAIERSDORF (DE)

(21) Appl. No.: 14/341,886

(22) Filed: Jul. 28, 2014

(30) Foreign Application Priority Data
Aug. 7, 2013 (DE) 102013215591.3

(51) Int. Cl. G02B 27/22; G01R 33/28

(52) U.S. Cl. CPC G02B 27/2214; G01R 33/283
USPC 359/463

(57) ABSTRACT

A medical imaging device having at least one lenticular image, a lenticular image for use in a medical imaging device and the use or positioning of a lenticular image in a medical imaging device is provided. In order to increase patient comfort during an examination, the medical imaging device comprises a hollow cylindrical opening in which a patient can be positioned for the recording of medical image data from the patient, wherein at least one lenticular image is arranged on an inner wall of the hollow cylindrical opening.

### CROSS-REFERENCE TO RELATED APPLICATIONS

This application claims priority to DE Application No. 102013215591.3, having a filing date of Aug. 7, 2013, the entire contents of which are hereby incorporated by reference

### FIELD OF TECHNOLOGY

The following relates to a medical imaging device having at least one lenticular image. The following also relates to a lenticular image for use in a medical imaging device and the use of a lenticular image in a medical imaging device.

### BACKGROUND

Medical imaging devices often have hollow cylindrical openings in which a patient is positioned for the recording of medical image data. The patient then lies within the hollow cylindrical opening during the examination. By way of example, the diameter of the hollow cylindrical opening of a typical magnetic resonance device is only 60 cm. For some time, magnetic resonance devices with an enlarged opening having a diameter of 70 cm have been used. These increase patient comfort because more free space is made available to the patient within the hollow cylindrical opening.

Nevertheless, many patients complain of claustrophobia and lack of space when they lie within the hollow cylindrical opening of a medical imaging device for an examination. Therefore, particularly in the case of claustrophobic patients, an examination often has to be interrupted. Increasing the diameter of the hollow cylindrical opening of a medical imaging device is technologically very complex, and is usually associated with high costs.

### SUMMARY

An aspect relates to increasing patient comfort during an examination in a medical imaging device.

An aspect further relates to a medical imaging device which has a hollow cylindrical opening in which a patient can be positioned for the recording of medical image data from the patient, wherein at least one lenticular image is arranged on the inner wall of the hollow cylindrical opening.

The medical imaging device can be a magnetic resonance device, a computed tomography device, a scintigraphic device, a positron emission tomography device or a single photon emission tomography device. The medical imaging device can be a combined medical imaging device. The hollow cylindrical opening of the medical imaging device can be a tunnel or a tunnel-like opening in which the patient can be positioned. A lenticular image is also known as a line grating image or a prism grating image. A lenticular image can have optical lenses and/or prisms so that, without further optical aids, a three-dimensional and/or space-enlarging effect, or impression, is created for an observer.

The lenticular image can be mounted on the inner wall of the hollow cylindrical opening. The lenticular image can be mounted by gluing onto the inner wall of the hollow cylindrical opening. The lenticular image can be mounted by means of a fastening apparatus onto the inner wall of the hollow cylindrical opening. In an exemplary embodiment, the lenticular image can be integrated into the inner wall of the hollow cylindrical opening. Then the diameter of the opening may not be reduced by the lenticular image. The inner wall of the hollow cylindrical opening of the medical imaging device can be configured such that integration of the lenticular image into the inner wall of the hollow cylindrical opening is possible. For example, the inner wall of the hollow cylindrical opening can have a depression for the lenticular image.

The lenticular image may be arranged at a suitable site within the hollow cylindrical opening so that it can be observed by a patient typically positioned for examination in the hollow cylindrical opening, during the examination. A typical positioning of a patient within the hollow cylindrical opening may involve positioning of the patient lying on his back. Therefore, the upper part and/or the lateral parts of the hollow cylindrical opening may be lined with the lenticular image. Maximum patient comfort is offered by a lining of substantially the whole hollow cylindrical opening with one or more lenticular images which are possibly different from one another.

Hollow cylindrical openings of medical imaging devices can have a diameter of 30 cm to 100 cm, typically of 50 cm to 80 cm, in particular a diameter of 60 cm to 70 cm. In order that the upper half of the hollow cylindrical opening can be lined, a width of the lenticular image of at least 60 cm, in particular at least 80 cm, or of at least 100 cm, or at least 120 cm is useful. Depending thereon at what length the hollow cylindrical opening of the medical imaging device is to be divided, the length of the lenticular image can be adapted thereto. For this purpose, the length of the lenticular image can be between 20 cm and 250 cm. If, for example, the whole hollow cylindrical opening of a magnetic resonance apparatus is to be lined, a length of the lenticular image between 80 cm and 160 cm is useful, in particular between 110 cm and 130 cm. The thickness of the lenticular image may not exceed 5 cm, in particular 3 cm, or 1 cm, or even 3 mm, so that the hollow cylindrical opening of the medical imaging device may not be significantly reduced by the lenticular image.

The lenticular image can create a three-dimensional and/or space-increasing effect or a spatial depth effect for the observing patient whilst the patient lies within the hollow cylindrical opening of the medical imaging device for the examination. Due to the presence of the lenticular image, the patient therefore perceives the diameter of the hollow cylindrical opening to be increased. The lenticular image has the result that the patient feels as if he were in an enlarged virtually-generated space. Depending on the design of the lenticular image, the depth effect can extend from a few centimeters to 50 cm. Due to the presence of the lenticular image, the patient perceives a free space enlarged by 10 cm to 30 cm. Animations of the lenticular image can also distract the patient during the medical examination. Furthermore, a suitably relaxing theme for the lenticular image can placate the patient during the examination.

By this means, the lenticular image contributes to increased patient comfort and increases, in particular, the cooperation rate particularly among patients prone to claustrophobia. The medical examination can be carried out in a more relaxed way and fewer examinations are subject to abandonment. This has a direct effect by increasing patient throughput for the medical imaging device.

One embodiment provides that the lenticular image may have at least one lenticular film and at least one theme image. The lenticular film may also be known as line grating film. In this context, the lenticular film may contain optical elements, for example, lenses or prisms which are arranged, for example, in a grid manner, so that the theme image has a three-dimensional and/or space-enlarging effect for an observer. A vertical arrangement of the optical elements or a vertical lens arrangement in relation to the observer may be used, so that a spatial effect is generated for the observer. The spatial effect can be generated in that the right eye of the observer sees a different theme image, or the theme image from another perspective, from the left eye of the observer. Herein, the lenticular image can be constructed in two layers. The rear layer, seen from the point of view of the observer, can be formed by the theme image and the front layer, seen from the point of view of the observer, can be formed by the lenticular film. The theme image can also be at least partially integrated into the lenticular film. The lenticular film can also be integrated just partially into the hollow cylindrical opening of the medical imaging device. In particular, just the theme image can be integrated into the hollow cylindrical opening.

Another embodiment provides that the lenticular film and the theme image may be matched to one another such that the theme image has a three-dimensional and/or space-enlarging effect, as seen by the eyes of a patient who is typically positioned in the hollow cylindrical opening of the medical imaging device. In an exemplary embodiment, it may be useful suitably to match the configuration of the theme image to the configuration of the optical elements of the lenticular film. The matching of the lenticular film and of the theme image can be carried out exclusively by means of a suitable calculation of the theme image. Pre-existing standard optical elements can be used for the lenticular film. In this regard, two theme images which show the same theme recorded from different perspectives can be arranged alternately divided into theme image strips. In a pre-determined configuration of the theme image, the optical elements of the lenticular film can also suitably be configured for generating the three-dimensional and/or space-enlarging effect. Thus, a three-dimensional and/or space-enlarging effect for a patient who is typically positioned within the medical imaging device may be created. A typical positioning of a patient within the hollow cylindrical opening involves the positioning of the patient lying on his back. In this arrangement, above all, the eye position of the patient relative to the lenticular image can be important. Proceeding from a standard head position of the patient in the medical imaging device can be done. This depends on the configuration of the positioning device for the patient, for example, the use of a cushion for positioning the head of the patient. Further, a typical value for the separation of the surface of the back of the head and the eyes must be assumed. This value can lie in the range between 16 cm and 28 cm, in particular between 20 cm and 24 cm. Further parameters for calculating the theme image and the lenticular film may be the diameter of the hollow cylindrical opening of the medical imaging device and/or the thickness of the lenticular image and/or the thickness of a possible background illumination of the lenticular image. The lenticular film and the theme image can be matched to one another such that, seen from an observing position, the theme image has a three-dimensional and/or space-enlarging effect, wherein the observing position is located between 16 cm and 28 cm, in particular between 20 cm and 24 cm above a surface of a patient positioning device in the medical imaging device. The three-dimensional and/or space-enlarging effect can offer the spatial depth effect for the observing patient.

Another embodiment provides that the lenticular image may include of non-magnetic materials. This embodiment may be useful if the medical imaging device is a magnetic resonance device. Through the use of non-magnetic materials, the influencing of the magnetic fields or high frequency waves in the magnetic resonance device caused by the lenticular image can be reduced or excluded. By this means, the production of artifacts on the images recorded by means of the magnetic resonance device is also prevented. For this purpose, the lenticular image can include largely or, completely of non-magnetic materials.

Another embodiment provides that the lenticular image may be configured to be curved, the radius of curvature of the lenticular image being adapted to the internal radius of the hollow cylindrical opening of the medical imaging device. For this purpose, the radius of curvature of the lenticular image can be between 20 cm and 50 cm. Values for the radius of curvature of the lenticular image are between 30 cm and 40 cm. The radius of curvature of the lenticular image can be adapted, in particular, to the internal radius of the hollow cylindrical opening so as to correspond essentially to the internal radius of the hollow cylindrical opening, or to deviate only slightly therefrom. The adaptation of the radius of curvature of the lenticular image also depends thereon whether the lenticular image is integrated into the inner wall of the hollow cylindrical opening or is mounted thereon. The theme image and the lenticular film of the lenticular image may be adapted to the curved configuration of the lenticular image, so that the lenticular image can maintain a three-dimensional and/or space-enlarging effect for an observer. This can be achieved by means of a specifically curved configuration of the optical elements of the lenticular film and/or by means of a calculation of the theme image specifically matched to the curved configuration of the lenticular image.

Another embodiment provides that the medical imaging device may have an illumination device which may comprise at least one light source and at least one light coupling-in device, the light coupling-in device being configured to deflect the light generated by the light source onto the lenticular image. The illumination device may illuminate the lenticular image. By means of the illumination, the space-enlarging and/or three-dimensional effect of the lenticular image can be increased. The light source can be integrated into the medical imaging device. An already existing light source of the medical imaging device can be used as the light source. Naturally, a light source specifically matched to the lenticular image can also be used within or outside of the hollow cylindrical opening of the medical imaging device. The light source can be an LED light source. The brightness of the light source can be controllable. The light source can also be configured such that the color of the light emerging from the light source can be changed. The light input device can be configured as an optical waveguide. Said waveguide may provide for optimum and/or even illumination of the lenticular images. Exemplary embodiments may include a configuration of the illumination device as background illumination for the lenticular image. The lenticular image can be illuminated from behind as seen by the observer. For this purpose, the light coupling-in device can be positioned, as seen by the observer of the lenticular image, mostly behind the lenticular image. The light coupling-in device and the lenticular image may have substantially the same breadth and length. The illumination device can be integrated at least partially into the inner wall of the hollow cylindrical opening of the medical imaging device.

Another embodiment provides that the light coupling-in device may comprise a film, wherein the film is arranged, as seen by the eyes of a patient positioned in the hollow cylindrical opening of the medical imaging device, behind the lenticular image, and the film is configured so as to enable illumination of the lenticular image by means of the light generated by the light source. The film can be configured so as to enable a largely even illumination of the lenticular image by means of the light generated by the light source. The film is therefore positioned, as seen by the patient, the observer of the lenticular image, behind the theme image and the lenticular film. A patient positioned in the medical imaging device may lie on his back. The film can be configured as an optical waveguide. The film can have substantially the same length and breadth as the lenticular image. The film may also be as thin as possible so that the diameter of the hollow cylindrical opening may not be reduced too greatly. The film can be thinner than 5 cm, in particular 3 cm, or 1 cm, or even 3 mm. The light source may be positioned laterally at the edges of the film. The light emerging from the light source can thus be coupled directly into the film. Optical elements which may distribute the light emerging from the light source can also be distributed over the entire lenticular image. In the case of a curved configuration of the lenticular image, the film can also be curved. The radius of curvature of the film can then be adapted to the radius of curvature of the lenticular image or can substantially correspond to the radius of curvature of the lenticular image.

Another embodiment provides that the illumination device may be comprised of non-magnetic materials. This embodiment may be useful if the medical imaging device is a magnetic resonance device. Through the use of non-magnetic materials, the influencing of the magnetic fields or high frequency waves in the magnetic resonance device by the illumination device can be reduced or excluded. By this means, the production of artifacts on the images recorded by means of the magnetic resonance device can also be prevented. For this purpose, the illumination device can be comprised largely or completely of non-magnetic materials.

Embodiments of the lenticular may be provided for use in a medical imaging device, the medical imaging device having a hollow cylindrical opening in which a patient can be positioned for the recording of medical image data from the patient, and wherein
the lenticular image is configured to be flexible such that, in a curved state, it has a radius of curvature which is adapted to the internal radius of the hollow cylindrical opening,
the lenticular image is comprised of non-magnetic materials, and
the lenticular image comprises at least one lenticular film and at least one theme image, wherein the lenticular film and the theme image are matched to one another such that the theme image has a three-dimensional and/or space-enlarging effect as seen by the eyes of a patient who is positioned in the hollow cylindrical opening of the medical imaging device if the lenticular image is arranged in the curved state on the inner wall of the hollow cylindrical opening.

One embodiment provides that the lenticular image may have an illumination device, wherein the illumination device may comprise at least one light source and at least one light coupling-in device, the light coupling-in device being configured to deflect the light generated by the light source onto the lenticular image. The illumination device can be configured to be separate from the lenticular image or to be integrated, at least partially, into the lenticular image and/or at least partially to be connected to the lenticular image. The illumination device can be comprised of non-magnetic materials.

### BRIEF DESCRIPTION

Some of the embodiments will be described in detail, with reference to the following figures, wherein like designations denote like members, wherein:

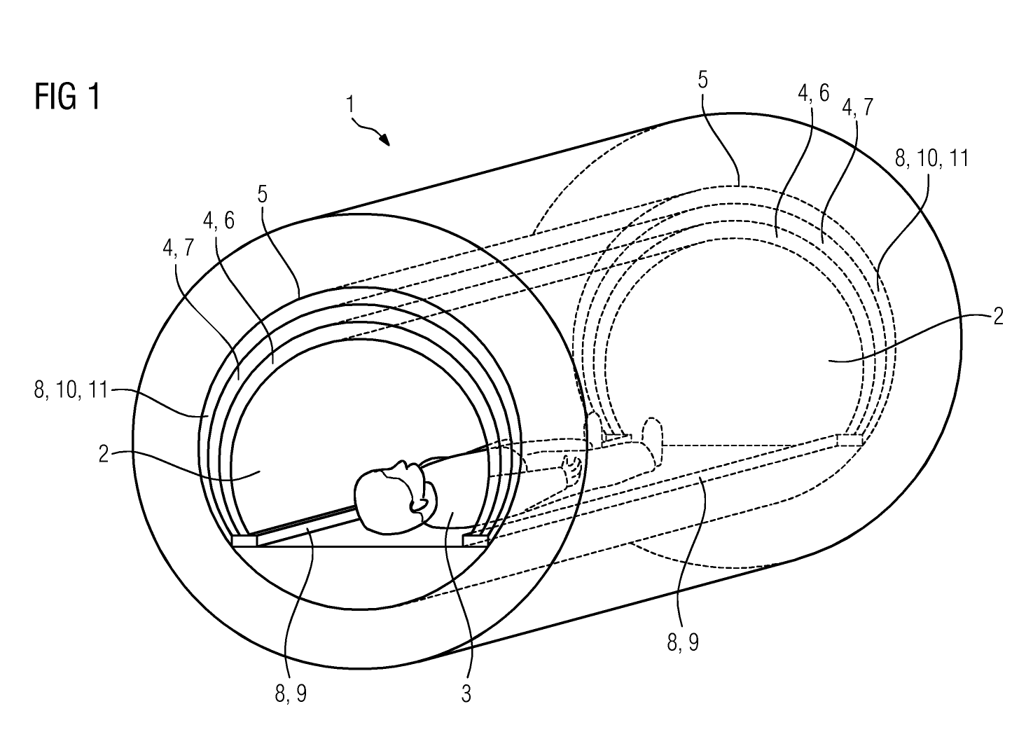

FIG. 1 is a view of a schematic representation of an embodiment of a medical imaging device; and

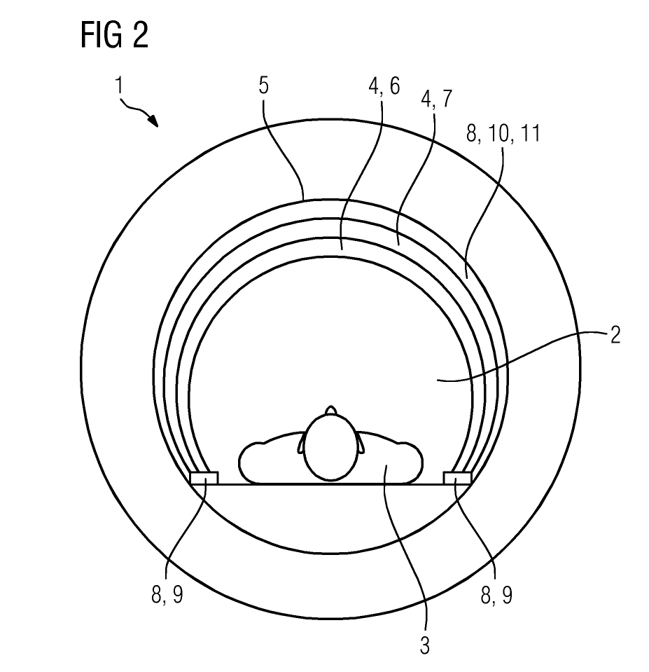

FIG. 2 is a cross-section through an embodiment of the medical imaging device, as shown in FIG. 1.

### DETAILED DESCRIPTION

FIG. 1 shows a view of an embodiment of a medical imaging device 1. The medical imaging device 1 has a hollow cylindrical opening 2. In this device, a patient 3 is positioned in a typical position on his back such that, during the examination, said patient can observe a lenticular image 4 fastened to the inner wall 5 of the hollow cylindrical opening 2. The lenticular image 4 has a lenticular film 6 and a theme image 7. Said lenticular image is illuminated by means of an illumination device 8 wherein the illumination device 8 has two light sources 9 and a light coupling-in device 10 with a film 11. The elements of the medical imaging device 1 are shown merely in sketch form in FIG. 1. The medical imaging device 1 can be, for example, a magnetic resonance device, a computed tomography device or a molecular imaging device.

The lenticular image 4 and the light coupling-in device 10 are positioned in shell-like manner on the inner wall 5 of the medical imaging device 1. Seen from the inner wall 5 in the direction toward the center of the medical imaging device 1, the light coupling-in device 10 constitutes the outer shell, the theme image 7 constitutes the central shell and the lenticular film 6 constitutes the inner shell. The light coupling-in device 10 also provides for a background illumination of the lenticular image 4. The optical elements of the lenticular film 6 are arranged between the eyes of the patient 3 and the theme image 7 such that a space-enlarging and/or three-dimensional impression of the theme image 7 is produced for the patient 3. This impression is enhanced through the background illumination by means of the illumination device 8.

The illumination device 8 comprises two light sources 9 which, in the case shown, are fastened to both sides of the inner wall 5 of the hollow cylindrical opening 2. The light sources 9 are realized as LED light strips which extend over the entire length of the hollow cylindrical opening 2. The light emerging from the light sources 9 is coupled into the film 11 of the light coupling-in device 10 at both ends of the film 11. The film 11 is configured as an optical wave guide in such a way that the light is evenly distributed over the entire film 11 and therefore the lenticular image 4 is homogeneously illuminated. For this purpose, suitable optical elements can be arranged in the film 11.

The lenticular film 6, the theme image 7 and the film 11 are arranged curved in the case shown. The radii of curvature of these parts are matched to the curvature of the inner wall 5 of the hollow cylindrical opening 2 of the medical imaging device 1. The matching of the radii of curvature is carried out in such a way that the elements lie essentially seamlessly on one another. In the case shown, the hollow cylindrical opening 2 is lined, over the entire length of the medical imaging device 1, with the lenticular image 4 and the light coupling-in device 10. Furthermore, the whole field of view of the patient 3 is covered by the lenticular image 4. For this purpose, the inner wall 5 of the hollow cylindrical opening 2 is covered, on the majority of the extent thereof, with the lenticular image 4. Such a size of the lenticular image 4 and of the background illumination is not always necessary. It is also possible for just part of the inner wall 5 to be lined with a lenticular image 4 in the longitudinal direction of the medical imaging device, without any severe reduction in patient comfort. The outer, lateral field of view of the patient also does necessarily not have to be lined with a lenticular image 4.

More than one lenticular image 4 can be mounted on the inner wall 5. It is also possible for more than two light sources 9 or only one light source 9 to be used. The light sources 9 also do not have to be placed at the position shown. The light coupling-in device 10, the theme image 7 or the lenticular film 6 may be integrated into the inner wall 5 of the hollow cylindrical opening 2. The outermost elements, or alternatively all the elements, can be integrated into the inner wall 5. By this means, the diameter of the hollow cylindrical opening 2 is not reduced due to the background illumination and/or the lenticular image 4. It is also possible to integrate the theme image 7 at least partially into the lenticular film 6.

FIG. 2 shows a cross-section through the medical imaging device 1 shown in FIG. 1. This view illustrates again the shell-shaped construction of the light coupling-in device 10, the theme image 7 and the lenticular film 6. The position of the light sources 9 is also emphasized. The light sources 9 enable herein not only illumination of the lenticular image 4, but also illumination of the interior of the hollow cylindrical opening 2.

The cross-section through the medical imaging device 1 as shown in FIG. 2 is set at the height of the head of the patient 3. A standard head position, a typical position and orientation of the head and therefore of the eyes of the patient 3 are shown. Starting from the standard head position, the known diameter of the hollow cylindrical opening 2 and the known thickness and position of the light coupling-in device 10 and the lenticular image 4, the lenticular film 6 and the theme image 7 can now be matched to one another such that the theme image 7 has a three-dimensional and/or space-enlarging effect when seen by the eyes of the patient 3. For this purpose, the theme image 7 can be at least partially integrated into the lenticular film 6. For this purpose, the theme image 7 can consist of a plurality of individual partial images and/or image strips which are calculated for dedicated use in the medical imaging device 1.

Although the invention has been illustrated and described in detail based on exemplary embodiments, the invention is not restricted by the examples given and other variations can be derived therefrom by a person skilled in the art without departing from the protective scope of the embodiment.

Embodiments described herein relate to a medical imaging device 1 having at least one lenticular image 4. The embodiments also relate to a lenticular image 4 for use in a medical imaging device 1 and the use of a lenticular image 4 in a medical imaging device 1. In order that the medical imaging device 1 increases patient comfort during an examination of the patient, the medical imaging device 1 may comprise a hollow cylindrical opening 2 in which a patient 3 can be positioned for the recording of medical image data from the patient 3, wherein at least one lenticular image 4 can be arranged on the inner wall 5 of the hollow cylindrical opening 2.

1. A medical imaging device comprising:
a hollow cylindrical opening that is configured to receive a patient for the recording of medical image data from the patient;
wherein at least one lenticular image is arranged on an inner wall of the hollow cylindrical opening.

2. The medical imaging device as claimed in claim 1, wherein the at least one lenticular image comprises at least one lenticular film and at least one theme image.

3. The medical imaging device as claimed in claim 2, wherein the at least one lenticular film and the at least one theme image are matched to one another such that the at least one theme image has a three-dimensional and/or space-enlarging effect, as seen by the eyes of the patient received by the hollow cylindrical opening of the medical imaging device.

4. The medical imaging device as claimed in claim 1, wherein the at least one lenticular image is made at least partially of non-magnetic materials.

5. The medical imaging device as claimed in claim 1, wherein the at least one lenticular image is curved, a radius of curvature of the at least one lenticular image being adapted to an internal radius of the hollow cylindrical opening of the medical imaging device.

6. The medical imaging device as claimed in claim 1, wherein the medical imaging device has an illumination device which comprises at least one light source and at least one light coupling-in device, the at least one light coupling-in device being configured to deflect the light emerging from the at least one light source onto the at least one lenticular image.

7. The medical imaging device as claimed in claim 6, wherein the at least one light coupling-in device comprises a film, wherein the film is arranged, as seen from the eyes of the patient received by the hollow cylindrical opening of the medical imaging device, behind the at least one lenticular image and the film is configured so as to enable illumination of the at least one lenticular image by means of the light generated by the at least one light source.

8. The medical imaging device as claimed in claim 6, wherein the illumination device is made at least partially of non-magnetic materials.

9. A lenticular image for use in a medical imaging device, the medical imaging device having a hollow cylindrical opening in which a patient is positioned for the recording of medical image data from the patient, and wherein:
the lenticular image is configured to be flexible such that, in a curved state, the lenticular image has a radius of curvature which is adapted to an internal radius of the hollow cylindrical opening,
the lenticular image is made at least partially of non-magnetic materials, and
the lenticular image comprises at least one lenticular film and at least one theme image, wherein the at least one lenticular film and the at least one theme image are matched to one another such that the at least one theme image has a three-dimensional and/or space-enlarging effect, as seen by the eyes of the patient positioned in the hollow cylindrical opening of the medical imaging device, if the lenticular image is arranged in the curved state on an inner wall of the hollow cylindrical opening.

10. The lenticular image as claimed in claim 9, further comprising an illumination device, wherein the illumination device comprises at least one light source and at least one light coupling-in device, the at least one light coupling-in device being configured to deflect the light emerging from the at least one light source onto the lenticular image.

11. Positioning at least one lenticular image as claimed in claim 9 in a medical imaging device.
